(19) United States
(12) Patent Application Publication
(10) Pub. No.: US 2025/0015781 A1
(43) Pub. Date: Jan. 9, 2025

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Akihiro IYAMA, Nagaokakyo-shi (JP); Toru YAMAJI, Nagaokakyo-shi (JP)

(21) Appl. No.: 18/891,039

(22) Filed: Sep. 20, 2024

Related U.S. Application Data
(63) Continuation of application No. PCT/JP2023/012260, filed on Mar. 27, 2023.
(60) Provisional application No. 63/324,848, filed on Mar. 29, 2022.

(51) Int. Cl. H03H 9/145; H03H 9/02; H03H 9/05

(52) U.S. Cl. CPC H03H 9/14541; H03H 9/02031; H03H 9/02157; H03H 9/0504

(57) ABSTRACT

An acoustic wave device includes a support, a piezoelectric layer on the support, an IDT electrode on the piezoelectric layer and including busbars and electrode fingers, and mass-added films on the electrode fingers. An acoustic reflection portion is provided in the support and overlaps at least a portion of the IDT electrode. d/p is about 0.5 or less. When viewed in an electrode finger orthogonal direction, a region in which the electrode fingers adjacent to each other overlap each other is an intersecting region including a central region, and first and second edge regions. At least a portion of the mass-added films overlaps the central region in plan view.

### CROSS REFERENCE TO RELATED APPLICATIONS

This application claims the benefit of priority to Provisional Application No. 63/324,848 filed on Mar. 29, 2022 and is a Continuation Application of PCT Application No. PCT/JP2023/012260 filed on Mar. 27, 2023. The entire contents of each application are hereby incorporated herein by reference.

### BACKGROUND OF THE INVENTION

### 1. Field of the Invention

The present invention relates to acoustic wave devices.

### 2. Description of the Related Art

In the related art, an acoustic wave device is widely used as a filter or the like of a mobile phone. In recent years, as described in U.S. Pat. No. 10,491,192, an acoustic wave device using a bulk wave in a thickness shear mode has been proposed. In the acoustic wave device, a piezoelectric layer is provided on a support body. A pair of electrodes are provided on the piezoelectric layer. The pair of electrodes face each other on the piezoelectric layer and are connected to potentials different from each other. An alternating current (AC) voltage is applied between the electrodes to excite the bulk wave in the thickness shear mode.

In the acoustic wave device described in U.S. Pat. No. 10,491,192, a plate wave mode and a harmonic wave thereof become strong unwanted waves. Therefore, in a case where the acoustic wave device is used in a filter device, there is a concern that filter characteristics are deteriorated.

### SUMMARY OF THE INVENTION

Example embodiments of the present invention provide acoustic wave devices that each reduce or prevent unwanted waves.

An acoustic wave device according to an example embodiment of the present invention includes a support including a support substrate, a piezoelectric layer on the support, an IDT electrode on the piezoelectric layer and including a pair of busbars facing each other and a plurality of electrode fingers, and a plurality of mass-added films on the plurality of electrode fingers. An acoustic reflection portion is provided in the support at a position overlapping at least a portion of the IDT electrode. In plan view in a lamination direction of the support and the piezoelectric layer, d/p is about 0.5 or less, where d is a thickness of the piezoelectric layer and p is a center-to-center distance between the electrode fingers adjacent to each other. Each of the plurality of electrode fingers includes a proximal end portion connected to a corresponding one of the pair of busbars and a distal end portion facing the proximal end portion, when viewed in an electrode finger orthogonal direction orthogonal or substantially orthogonal to an electrode finger extension direction in which the plurality of electrode fingers extend. A region in which the electrode fingers adjacent to each other overlap each other is an intersecting region, the intersecting region includes a central region, and a first edge region and a second edge region sandwiching the central region in the electrode finger extension direction and facing each other. At least a portion of each of the plurality of mass-added films overlaps the central region in plan view. The mass-added film on the electrode finger is one of the mass-added film continuously provided from a proximal end portion side to a distal end portion side and the mass-added film intermittently provided from the proximal end portion side to the distal end portion side. When a dimension of the mass-added film in the electrode finger orthogonal direction is defined as a width of the mass-added film, the width changes from a portion provided on the proximal end portion side to a portion provided on the distal end portion side in at least a portion of the mass-added film.

According to example embodiments of the present invention, it is possible to provide acoustic wave devices that each reduce or prevent an unwanted wave.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic sectional view taken along line I-I in FIG. 1.

FIG. 3 is a view showing admittance frequency characteristics in the first example embodiment of the present invention and a comparative example.

FIG. 4 is a view showing admittance frequency characteristics on a lower range side than a resonant frequency in the first example embodiment of the present invention and the comparative example.

FIG. 5 is a view showing admittance frequency characteristics on a higher range side than an anti-resonant frequency in the first example embodiment of the present invention and the comparative example.

FIG. 6 is a schematic plan view of an acoustic wave device according to a second example embodiment of the present invention.

FIG. 7 is a schematic plan view of an acoustic wave device according to a third example embodiment of the present invention.

FIG. 8 is a schematic plan view of an acoustic wave device according to a fourth example embodiment of the present invention.

FIG. 9 is a schematic plan view of an acoustic wave device according to a fifth example embodiment of the present invention.

FIG. 10 is a schematic plan view of an acoustic wave device according to a sixth example embodiment of the present invention.

FIG. 11 is a schematic plan view of an acoustic wave device according to a seventh example embodiment of the present invention.

FIG. 12 is a schematic plan view of an acoustic wave device according to an eighth example embodiment of the present invention.

FIG. 13 is a schematic plan view of an acoustic wave device according to a ninth example embodiment of the present invention.

FIG. 14 is a schematic plan view of an acoustic wave device according to a tenth example embodiment of the present invention.

FIG. 15 is a circuit diagram of a filter device according to an eleventh example embodiment of the present invention.

FIG. 16A is a schematic perspective view showing an appearance of an acoustic wave device using a bulk wave in a thickness shear mode, and FIG. 16B is a plan view showing an electrode structure on a piezoelectric layer.

FIG. 17 is a sectional view of a portion taken along line A-A in FIG. 16A.

FIG. 18A is a schematic elevational sectional view showing a Lamb wave that propagates through a piezoelectric film of the acoustic wave device, and FIG. 18B is a schematic elevational sectional view showing a bulk wave in a thickness shear mode that propagates through the piezoelectric film of the acoustic wave device.

FIG. 19 is a view showing an amplitude direction of the bulk wave in the thickness shear mode.

FIG. 20 is a view showing resonance characteristics of the acoustic wave device using the bulk wave in the thickness shear mode.

FIG. 21 is a view showing a relationship between d/p and a fractional bandwidth as a resonator in a case where a center-to-center distance between electrodes adjacent to each other is defined as p and a thickness of a piezoelectric layer is defined as d.

FIG. 22 is a plan view of the acoustic wave device using the bulk wave in the thickness shear mode.

FIG. 23 is a view showing resonance characteristics of an acoustic wave device of a reference example in which spurious appears.

FIG. 24 is a view showing a relationship between a fractional bandwidth and a phase rotation amount of an impedance of the spurious standardized at 180 degrees as a magnitude of the spurious.

FIG. 25 is a view showing a relationship between d/2p and a metallization ratio MR.

FIG. 26 is a view showing a map of the fractional bandwidth with respect to Euler angles (0°, θ, ψ) of LiNbO₃ in a case where d/p is infinitely close to 0.

FIG. 27 is an elevational sectional view of an acoustic wave device including an acoustic multilayer film.

### DETAILED DESCRIPTION OF THE EXAMPLE EMBODIMENTS

Hereinafter, the present invention will be clarified by describing specific example embodiments of the present invention with reference to the drawings.

Each example embodiment described in the present specification is merely an example, and configurations can be partially replaced or combined with each other between different example embodiments.

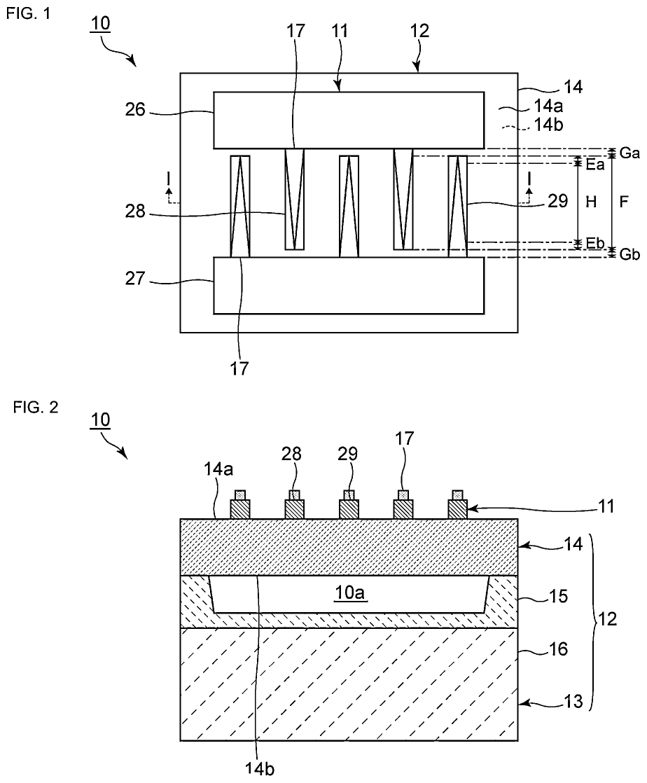

FIG. 1 is a schematic plan view of an acoustic wave device according to a first example embodiment of the present invention. FIG. 2 is a schematic sectional view taken along line I-I in FIG. 1.

As shown in FIG. 1, an acoustic wave device 10 includes a piezoelectric substrate 12 and an IDT electrode 11. As shown in FIG. 2, the piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. However, the support 13 may be configured only by the support substrate 16.

The piezoelectric layer 14 includes a first main surface 14a and a second main surface 14b. The first main surface 14a and the second main surface 14b face each other. Of the first main surface 14a and the second main surface 14b, the second main surface 14b is located on the support 13 side.

As a material of the support substrate 16, for example, a semiconductor such as silicon, ceramics such as aluminum oxide, or the like can be used. As a material of the insulating layer 15, for example, an appropriate dielectric such as silicon oxide or tantalum oxide can be used. For example, the piezoelectric layer 14 is a lithium niobate layer such as a LiNbO₃ layer, or a lithium tantalate layer such as a LiTaO₃ layer.

As shown in FIG. 2, a recess portion is provided in the insulating layer 15. The piezoelectric layer 14 is provided on the insulating layer 15 to close the recess portion. As a result, a hollow portion is provided. The hollow portion is a cavity portion 10a. In the present example embodiment, the support 13 and the piezoelectric layer 14 are disposed such that a portion of the support 13 and a portion of the piezoelectric layer 14 face each other with the cavity portion 10a interposed therebetween. However, the recess portion in the support 13 may be provided over the insulating layer 15 and the support substrate 16. Alternatively, the recess portion provided only in the support substrate 16 may be closed by the insulating layer 15. The recess portion may be provided in the piezoelectric layer 14. The cavity portion 10a may be, for example, a through-hole provided in the support 13.

The IDT electrode 11 is provided on the first main surface 14a of the piezoelectric layer 14. In plan view, at least a portion of the IDT electrode 11 overlaps the cavity portion 10a of the piezoelectric substrate 12. In the present specification, the description of “in plan view” means that an object is viewed in a lamination direction of the support 13 and the piezoelectric layer 14 from a direction corresponding to an upward direction in FIG. 2. In FIG. 2, for example, the piezoelectric layer 14 is positioned on an upper side of the support substrate 16 and the piezoelectric layer 14.

As shown in FIG. 1, the IDT electrode 11 includes one pair of busbars and a plurality of electrode fingers. Specifically, the one pair of busbars are a first busbar 26 and a second busbar 27. The first busbar 26 and the second busbar 27 face each other. Specifically, the plurality of electrode fingers include a plurality of first electrode fingers 28 and a plurality of second electrode fingers 29. One end of each of the plurality of first electrode fingers 28 is connected to the first busbar 26. One end of each of the plurality of second electrode fingers 29 is connected to the second busbar 27. The plurality of first electrode fingers 28 and the plurality of second electrode fingers 29 are interdigitated with each other. The IDT electrode 11 may include a single metal film, or may include a laminated metal film.

Hereinafter, the first busbar 26 and the second busbar 27 may be simply referred to as a busbar. The first electrode finger 28 and the second electrode finger 29 may be simply referred to as an electrode finger. Each electrode finger includes a distal end portion and a proximal end portion. The proximal end portion is a portion of the electrode finger connected to the busbar. When a direction in which the plurality of electrode fingers extend is defined as an electrode finger extension direction, the proximal end portion and the distal end portion face each other in the electrode finger extension direction.

Here, a direction orthogonal or substantially orthogonal to the electrode finger extension direction is referred to as an electrode finger orthogonal direction. When a direction in which the electrode fingers adjacent to each other face each other is defined as an electrode finger facing direction, the electrode finger facing direction is parallel or substantially parallel to the electrode finger orthogonal direction. When the IDT electrode 11 is viewed from the electrode finger orthogonal direction, a region in which the electrode fingers adjacent to each other overlap each other is an intersecting region F. The intersecting region F is a region of the piezoelectric layer 14 which is defined based on a configuration of the IDT electrode 11.

The intersecting region F includes a central region H and a pair of edge regions. The pair of edge regions are disposed to interpose the central region H therebetween in the electrode finger extension direction. Specifically, the pair of edge regions includes a first edge region Ea and a second edge region Eb. The first edge region Ea is located on the first busbar 26 side. The second edge region Eb is located on the second busbar 27 side.

Regions located between the intersecting region F and the pair of busbars are a pair of gap regions. Specifically, the pair of gap regions includes a first gap region Ga and a second gap region Gb. The first gap region Ga is located between the first busbar 26 and the first edge region Ea. The second gap region Gb is located between the second busbar 27 and the second edge region Eb. Similarly to the intersecting region F, each of the gap regions is a region of the piezoelectric layer 14 which is defined based on the configuration of the IDT electrode 11.

The acoustic wave device 10 according to the present example embodiment is an acoustic wave resonator configured to use a bulk wave in a thickness shear mode. More specifically, in the acoustic wave device 10, in a case where a thickness of the piezoelectric layer 14 is defined as d and a center-to-center distance between the electrode fingers adjacent to each other is defined as p, d/p is, for example, about 0.5 or less. As a result, the bulk wave in the thickness shear mode is suitably excited. When viewed in the electrode finger orthogonal direction, an excitation region is a region in which the electrode fingers adjacent to each other overlap each other and a region between the centers of the electrode fingers adjacent to each other. That is, the intersecting region F includes a plurality of excitation regions. In each excitation region, the bulk wave of the thickness shear mode is excited.

The cavity portion 10a shown in FIG. 2 is an acoustic reflection portion. The acoustic reflection portion can effectively confine energy of an acoustic wave on the piezoelectric layer 14 side. It is sufficient that the acoustic reflection portion is provided in the support at a position that overlaps at least a portion of the IDT electrode in plan view. For example, an acoustic reflection film such as an acoustic multilayer film (to be described later) may be provided as the acoustic reflection portion on a surface of the support.

Returning to FIG. 1, a mass-added film 17 is provided on the plurality of electrode fingers. More specifically, in the present example embodiment, the mass-added film 17 is provided one by one on all of the electrode fingers. The mass-added film 17 is continuously provided from the proximal end portion to the distal end portion of the electrode finger. It is sufficient that each of at least a portion of the plurality of mass-added films 17 overlaps the central region H in plan view.

The width of the mass-added film 17 is continuously changed in the mass-added film 17 from a portion provided on the proximal end portion side of the electrode finger to a portion provided on the distal end portion side of the electrode finger. More specifically, in the present example embodiment, the width of the mass-added film 17 is changed in the mass-added film 17 so as to narrow from the portion provided on the proximal end portion side of the electrode finger to the portion provided on the distal end portion side of the electrode finger. However, the change in width of the mass-added film 17 is not limited to the above-described configuration. The width of the mass-added film 17 is a dimension of the mass-added film 17 in the electrode finger orthogonal direction.

The mass-added film 17 is made of silicon oxide, for example. In the present specification, the fact that a certain member is made of a certain material includes a case where an amount of impurity is included to the extent that the electric characteristics of the acoustic wave device do not significantly deteriorate. The material of the mass-added film 17 is not limited to the above-described material.

One of the unique features of the present example embodiment is that the width of the mass-added film 17 is changed from the portion provided on the proximal end portion side of the electrode finger to the portion provided on the distal end portion side of the electrode finger, in at least a portion of the mass-added film 17. As a result, it is possible to reduce or prevent the unwanted waves. This advantageous effect will be described in detail below by comparing the present example embodiment with a comparative example.

The comparative example is different from the first example embodiment in that the mass-added film is not provided. In the first example embodiment and the comparative example, the admittance frequency characteristics were compared.

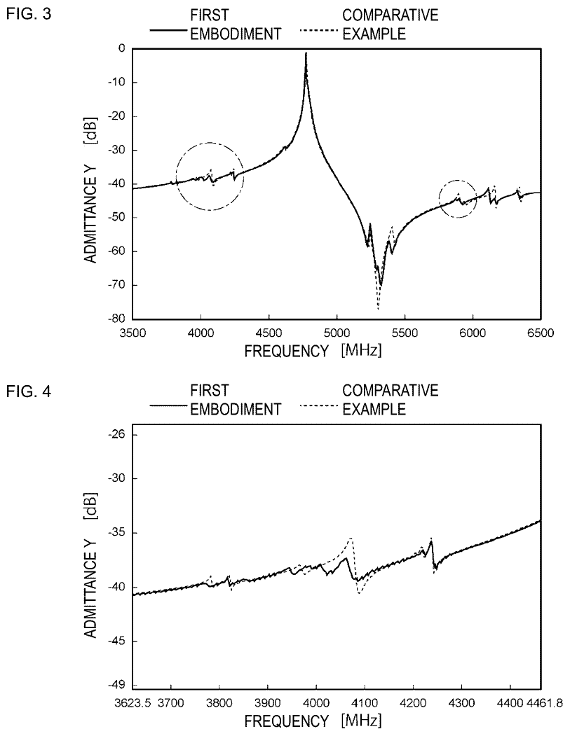

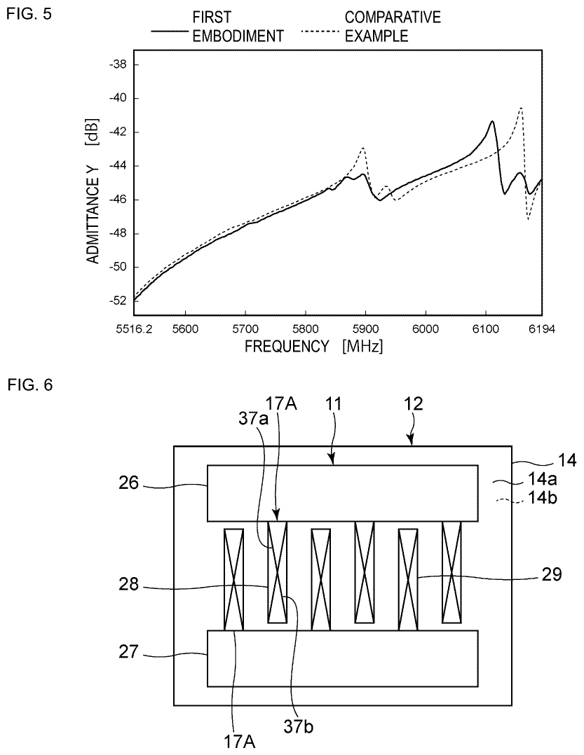

FIG. 3 is a view showing admittance frequency characteristics in the first example embodiment and the comparative example. FIG. 4 is a view showing admittance frequency characteristics on a lower range side than a resonant frequency in the first example embodiment and the comparative example. FIG. 5 is a view showing admittance frequency characteristics on a higher range side than an anti-resonant frequency in the first example embodiment and the comparative example. In addition, FIGS. 4 and 5 show the respective admittance frequency characteristics in the frequency ranges in the vicinity of the portions surrounded by the one-dot chain line in FIG. 3.

In the comparative example, unwanted waves are generated in the vicinity of the frequency ranges surrounded by the one-dot chain line in FIG. 3. The unwanted waves are generated in a frequency range on a lower range side than the resonant frequency and a frequency range on a higher range side than the anti-resonant frequency. These unwanted waves are caused by a plate wave and a harmonic wave thereof. As shown in FIGS. 4 and 5, it can be seen that the unwanted waves are reduced or prevented in the first example embodiment than in the comparative example.

This is because, as shown in FIG. 1, the width of the mass-added film 17 is changed in the electrode finger extension direction. As a result, the frequency at which the unwanted waves are excited can be dispersed, and the strength of the unwanted waves as a whole can be reduced.

In addition, the mass-added film 17 need not be necessarily provided on all of the electrode fingers. The plurality of electrode fingers may include electrode fingers on which the mass-added film 17 is not provided. However, it is preferable that the mass-added film 17 is provided on all of the electrode fingers. As a result, it is possible to effectively reduce or prevent unwanted waves.

In the first example embodiment, the IDT electrode 11 is provided on the first main surface 14a of the piezoelectric layer 14. However, it is sufficient that the IDT electrode 11 is provided on the first main surface 14a or the second main surface 14b of the piezoelectric layer 14. It is sufficient that the plurality of mass-added films 17 are provided on the plurality of electrode fingers in the IDT electrode 11. Even in a case where the IDT electrode 11 is provided on the second main surface 14b, it is possible to reduce or prevent the unwanted waves, similarly to the first example embodiment.

As described above, the mass-added film 17 is made of silicon oxide, for example. However, the mass-added film 17 may be made of a dielectric other than silicon oxide. In this case, it is preferable that the density of the mass-added film 17 is higher than the density of silicon oxide. Specifically, for example, it is preferable that the mass-added film 17 is made of tantalum oxide or the like. As a result, the thickness of the mass-added film 17 can be reduced. As a result, it is possible to reduce or prevent the variation in the shape of the mass-added film 17.

Alternatively, the mass-added film 17 may be made of an appropriate metal. Even in this case, the thickness of the mass-added film 17 can be reduced, and it is possible to reduce or prevent the variation in the shape of the mass-added film 17.

As shown in FIG. 1, in plan view, the plurality of mass-added films 17 overlap at least one gap region of the pair of gap regions and the intersecting region F. More specifically, in plan view, the mass-added film 17 provided on the first electrode finger 28 overlaps the central region H, the first edge region Ea, the second edge region Eb, and the first gap region Ga. In plan view, the mass-added film 17 provided on the second electrode finger 29 overlaps the central region H, the first edge region Ea, the second edge region Eb, and the second gap region Gb. However, as described above, it is sufficient that each mass-added film 17 overlaps the central region H in plan view.

In plan view, the plurality of mass-added films 17 may overlap both of the gap regions and the intersecting region F. In this case, for example, the mass-added film 17 may extend from a portion on the first electrode finger 28 to a portion on the piezoelectric layer 14. The portion of the mass-added film 17 that is directly provided on the piezoelectric layer 14 overlaps the second gap region Gb in plan view. Similarly, the other mass-added films 17 may extend from a portion on the second electrode finger 29 to a portion on the piezoelectric layer 14.

The shape of the mass-added film 17 in plan view is an isosceles triangle or substantially an isosceles. More specifically, the base side of the isosceles triangle overlaps the proximal end portion of the electrode finger in plan view. However, the shape of the mass-added film 17 in plan view is not limited to the above shape, and may be, for example, a triangle other than the isosceles triangle, a trapezoid, or a substantially semi-elliptical shape.

In the first example embodiment, the width of the mass-added film 17 is continuously and monotonically narrowed in the mass-added film 17 from the portion provided on the proximal end portion side of the electrode finger to the portion provided on the distal end portion side of the electrode finger. Therefore, in the mass-added film 17, the width of the portion provided on the proximal end portion side of the electrode finger is wider than the width of the portion provided on the distal end portion side of the electrode finger.

The width of the mass-added film 17 may be changed stepwise. In this case, the width of the mass-added film 17 may be monotonically narrowed in the mass-added film 17 from the portion provided on the proximal end portion side of the electrode finger to the portion provided on the distal end portion side of the electrode finger. In this case, in the mass-added film 17, the width of the portion provided on the proximal end portion side of the electrode finger is equal to or wider than the width of the portion provided on the distal end portion side of the electrode finger.

Alternatively, the width of the mass-added film 17 may be continuously or stepwise and monotonically widened in the mass-added film 17 from the portion provided on the proximal end portion side of the electrode finger to the portion provided on the distal end portion side of the electrode finger. That is, in the mass-added film 17, one width of the portion provided on the proximal end portion side of the electrode finger and the portion provided on the distal end portion side of the electrode finger may be equal to or wider than the other width of those portions.

It is sufficient that the width of at least a portion of at least one mass-added film 17 is changed in the electrode finger extension direction. For example, in at least a portion of at least one mass-added film 17, the width may be continuously changed in the mass-added film 17 from the portion provided on the proximal end portion side of the electrode finger to the portion provided on the distal end portion side of the electrode finger.

Specifically, for example, one mass-added film 17 may include a portion having a triangular or substantially triangular shape in plan view and a portion connected to the base of the triangle and having a rectangular or substantially rectangular shape in plan view. In this case, the width of a portion of the mass-added film 17 is continuously changed in the electrode finger extension direction. Even in this case, it is possible to reduce or prevent the unwanted waves.

However, it is preferable that at least a portion of the width of all of the mass-added films 17 is changed in the electrode finger extension direction. As a result, it is possible to effectively reduce or prevent unwanted waves.

In the following, examples of the mass-added film other than the first example embodiment will be described in the second to ninth example embodiments. The second to ninth example embodiments are different from the first example embodiment only in the configuration of the mass-added film. Even in the second to ninth example embodiments, it is possible to reduce or prevent the unwanted waves, similarly to the first example embodiment.

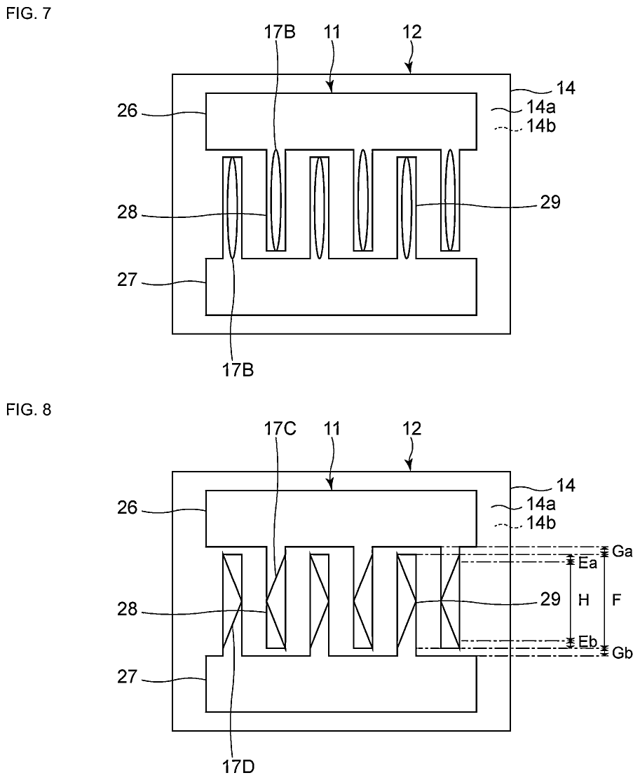

FIG. 6 is a schematic plan view of an acoustic wave device according to the second example embodiment. In FIG. 6, the IDT electrode 11 having the same or substantially the same configuration as in the first example embodiment is schematically shown. The same applies to the schematic plan views of FIG. 7 and subsequent drawings.

As shown in FIG. 6, in the second example embodiment, the width of each mass-added film 17A is continuously changed from the portion provided on the proximal end portion side of the electrode finger to the portion provided on the distal end portion side of the electrode finger. Specifically, in the mass-added film 17A, the width is changed so as to narrow from the portion provided on the proximal end portion side of the electrode finger to the portion provided on the distal end portion side of the electrode finger, and then the width is changed so as to widen.

More specifically, the mass-added film 17A includes a first portion 37a and a second portion 37b. The first portion 37a is a portion in which the width is changed so as to narrow from the portion provided on the proximal end portion side of the electrode finger to the portion provided on the distal end portion side of the electrode finger. The second portion 37b is a portion in which the width is changed so as to widen from the portion provided on the proximal end portion side of the electrode finger to the portion provided on the distal end portion side of the electrode finger. In each mass-added film 17A, the first portion 37a and the second portion 37b are connected to each other.

In the second example embodiment, the shapes of the first portion 37a and the second portion 37b of the mass-added film 17A in plan view are both isosceles triangles or substantially isosceles triangles. However, the shapes of the first portion 37a and the second portion 37b in plan view are not limited to the above shapes, and may be, for example, a triangle other than the isosceles triangle, a trapezoid, or a substantially semi-elliptical shape. The shapes of the first portion 37a and the second portion 37b in plan view may be different from each other.

FIG. 7 is a schematic plan view of an acoustic wave device according to the third example embodiment.

In the first example embodiment and the second example embodiment, the outer peripheral edge of the mass-added film in plan view has a shape in which straight lines are connected to each other. On the other hand, in the third example embodiment shown in FIG. 7, the shape of the mass-added film 17B in plan view is a shape including a curve. More specifically, the shape of the mass-added film 17B in plan view is elliptical or substantially elliptical. Therefore, in the mass-added film 17B, the width is changed in the mass-added film 17B so as to widen from the portion provided on the proximal end portion side of the electrode finger to the portion provided on the distal end portion side of the electrode finger, and then the width is changed so as to narrow.

For example, in the mass-added film 17B, the width may be changed in the mass-added film 17B so as to narrow from the portion provided on the proximal end portion side of the electrode finger to the portion provided on the distal end portion side of the electrode finger, and then the width may be changed so as to widen.

FIG. 8 is a schematic plan view of an acoustic wave device according to the fourth example embodiment.

In the fourth example embodiment, the shape of the mass-added film 17C provided on the first electrode finger 28 and the shape of the mass-added film 17D provided on the second electrode finger 29 are different from each other. Specifically, the shapes of the mass-added film 17C and the mass-added film 17D are line-symmetrical when an axis extending in the electrode finger extension direction is defined as a symmetry axis.

In the mass-added film 17C, the width is changed so as to widen in the mass-added film 17C from the portion provided on the proximal end portion side of the electrode finger to the portion provided on the distal end portion side of the electrode finger, and then the width is changed so as to narrow. The same applies to the mass-added film 17D.

The shape of the mass-added film 17C in plan view is a triangle or substantially a triangle. More specifically, the base side of the triangle overlaps one end edge portion of the electrode finger in the electrode finger orthogonal direction in plan view. The same applies to the mass-added film 17D. However, the shapes of the mass-added film 17C and the mass-added film 17D in plan view are not limited to the above shapes, and may be, for example, a trapezoidal or a substantially semi-elliptical shape.

In plan view, the mass-added film 17C and the mass-added film 17D do not overlap a region on an outer side portion of the intersecting region F in the electrode finger extension direction. However, the mass-added film 17C and the mass-added film 17D may be provided from the proximal end portion to the distal end portion on the electrode finger.

In the present example embodiment, the shapes of the mass-added film 17C and the mass-added film 17D have a line-symmetrical relationship. The shapes of the mass-added film 17C and the mass-added film 17D may have a point-symmetrical relationship.

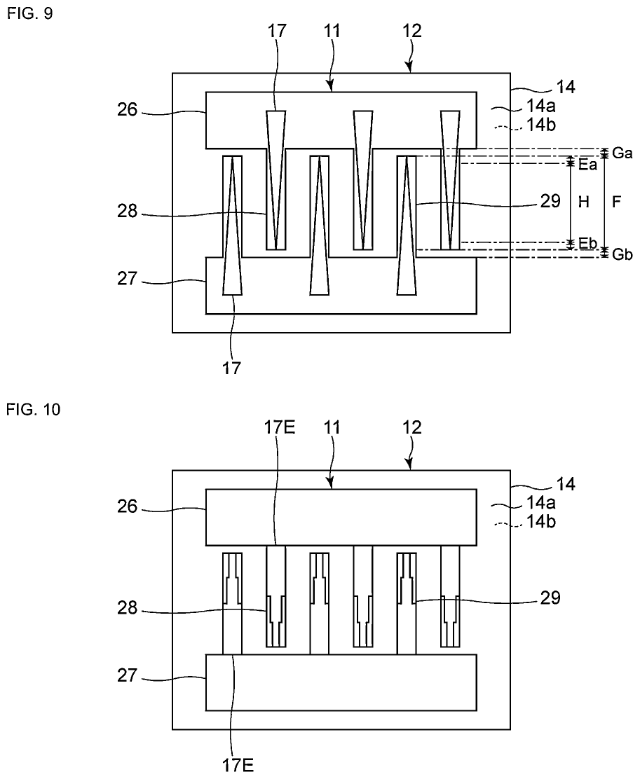

FIG. 9 is a schematic plan view of an acoustic wave device according to the fifth example embodiment.

In the first to third example embodiments, each mass-added film overlaps the intersecting region and one gap region in plan view. On the other hand, in the fifth example embodiment shown in FIG. 9, each mass-added film 17 overlaps the intersecting region F, one gap region, and a region in which one busbar is provided in plan view. That is, each mass-added film 17 is provided from the electrode finger to the busbar.

More specifically, in plan view, the mass-added film 17 provided on the first electrode finger 28 overlaps the central region H, the first edge region Ea, the second edge region Eb, the first gap region Ga, and the region in which the first busbar 26 is provided. In plan view, the mass-added film 17 provided on the second electrode finger 29 overlaps the central region H, the first edge region Ea, the second edge region Eb, the second gap region Gb, and the region in which the second busbar 27 is provided.

The shape of the mass-added film 17 in plan view is an isosceles triangle or substantially an isosceles, similarly to the first example embodiment. However, the shape of the mass-added film 17 in plan view is not limited to the above-described shape.

FIG. 10 is a schematic plan view of an acoustic wave device according to the sixth example embodiment.

In the first to fifth example embodiments, the width of the mass-added film is continuously changed in the mass-added film from the portion provided on the proximal end portion side of the electrode finger to the portion provided on the distal end portion side of the electrode finger. On the other hand, in the sixth example embodiment shown in FIG. 10, the width of the mass-added film 17E is changed in the mass-added film 17E stepwise from the portion provided on the proximal end portion side of the electrode finger to the portion provided on the distal end portion side of the electrode finger.

Specifically, in the mass-added film 17E, portions having different widths are connected to each other. The width of each portion is constant or substantially constant in the electrode finger extension direction. Therefore, the width of the mass-added film 17E is changed stepwise in the electrode finger extension direction. More specifically, in the mass-added film 17E of the sixth example embodiment, the width is changed in the mass-added film 17E so as to narrow from the portion provided on the proximal end portion side of the electrode finger to the portion provided on the distal end portion side of the electrode finger.

However, for example, in the mass-added film 17E, the width may be changed in the mass-added film 17E so as to widen from the portion provided on the proximal end portion side of the electrode finger to the portion provided on the distal end portion side of the electrode finger. Alternatively, for example, in the mass-added film 17E, the width may be changed to narrow in the mass-added film 17E from the portion provided on the proximal end portion side of the electrode finger to the portion provided on the distal end portion side of the electrode finger and then the width may be changed so as to widen.

In at least a portion of at least one mass-added film 17E, it is sufficient that the width is changed in the mass-added film 17E stepwise from the portion provided on the proximal end portion side of the electrode finger to the portion provided on the distal end portion side of the electrode finger.

In the sixth example embodiment, similarly to the first to fifth example embodiments, the mass-added film 17E is continuously provided from the proximal end portion side toward the distal end portion side of the electrode finger. The mass-added film on the electrode finger may be one of the mass-added film continuously provided from the proximal end portion side to the distal end portion side of the electrode finger and the mass-added film intermittently provided from the proximal end portion side to the distal end portion side.

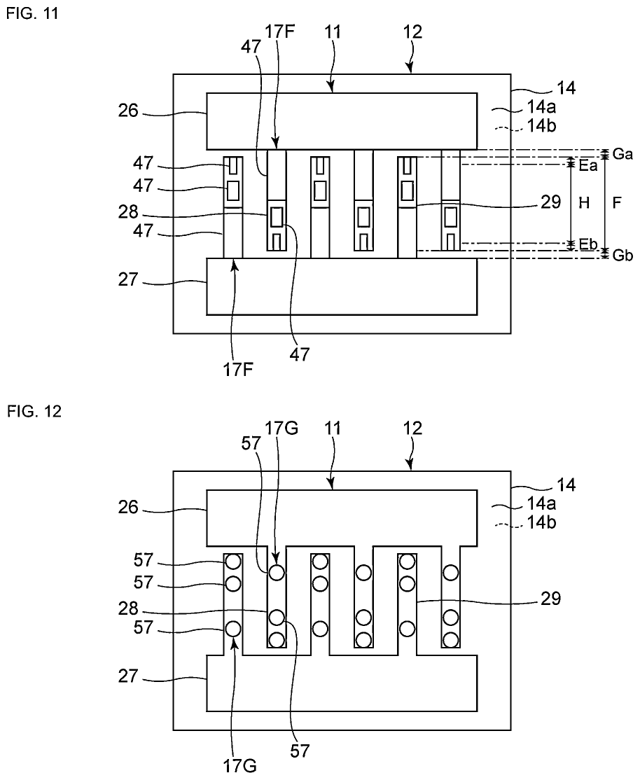

FIG. 11 is a schematic plan view of an acoustic wave device according to the seventh example embodiment.

In the seventh example embodiment, the mass-added film 17F is intermittently provided from the proximal end portion side toward the distal end portion side of the electrode finger. More specifically, the mass-added film 17F includes a plurality of film portions 47 arranged in the electrode finger extension direction. The width of each film portion 47 is constant or substantially constant in the electrode finger extension direction. On the other hand, the widths of the film portions 47 adjacent to each other in the electrode finger extension direction are different from each other. That is, the width of the mass-added film 17F is changed in the mass-added film 17F stepwise from the portion provided on the proximal end portion side of the electrode finger to the portion provided on the distal end portion side of the electrode finger.

As in the seventh example embodiment, in a case where each mass-added film 17F includes a plurality of film portions 47, it is sufficient that at least a portion of at least one film portion 47 of each mass-added film 17F overlaps the central region H in plan view. The number of film portions 47 in each mass-added film 17F is not particularly limited.

FIG. 12 is a schematic plan view of an acoustic wave device according to the eighth example embodiment.

In the eighth example embodiment, the width of each film portion 57 of the mass-added film 17G is not constant. Specifically, the shape of each film portion 57 in plan view is circular or substantially circular. Therefore, the width of the film portion 57 is continuously changed in the electrode finger extension direction. More specifically, in the film portion 57, the width is changed in the film portion 57 so as to widen from the portion provided on the proximal end portion side of the electrode finger to the portion provided on the distal end portion side of the electrode finger, and then the width is changed so as to narrow.

In at least a portion of the film portion 57, it is sufficient that the width is changed from the portion provided on the proximal end portion side of the electrode finger to the portion provided on the distal end portion side of the electrode finger. More specifically, the shape of the film portion 57 in plan view may be, for example, a triangular or substantially triangular shape, a polygonal shape, an elliptical or substantially elliptical shape, or an elongated shape.

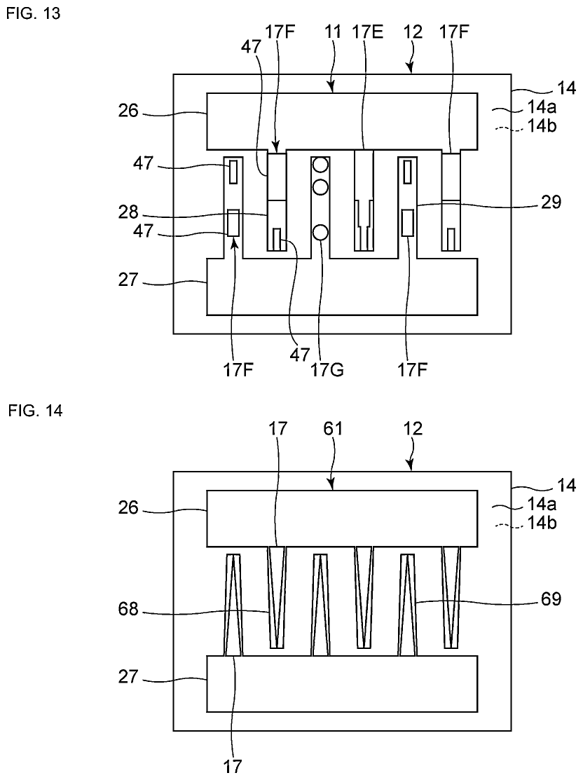

FIG. 13 is a schematic plan view of an acoustic wave device according to the ninth example embodiment.

In the ninth example embodiment, shapes of the plurality of mass-added films in plan view are different from each other. For example, the mass-added film 17E having the same or substantially the same configuration as that of the sixth example embodiment is provided on a certain first electrode finger 28. The mass-added film 17F having the same or substantially the same configuration as that of the seventh example embodiment is provided on the other first electrode finger 28. The mass-added film 17F having the same or substantially the same configuration as that of the seventh example embodiment is provided on a certain second electrode finger 29. The mass-added film 17G having the same or substantially the same configuration as that of the eighth example embodiment is provided on the other second electrode finger 29.

As in the ninth example embodiment, the mass-added film on at least one electrode finger may be the mass-added film 17E that is continuously provided from the proximal end portion side to the distal end portion side of the electrode finger. The mass-added film on at least one electrode finger may be the mass-added film 17F that is intermittently provided from the proximal end portion side to the distal end portion side of the electrode finger.

The example shown in FIG. 13 is an example, and it is sufficient that the mass-added film of any configuration according to example embodiments of the present invention is provided on the plurality of electrode fingers.

In the first to ninth example embodiments, the width of each electrode finger is constant or substantially constant. The width of the electrode finger is a dimension of the electrode finger in the electrode finger orthogonal direction. However, the width of the electrode finger may be changed in the electrode finger extension direction. This example is described in the tenth example embodiment.

FIG. 14 is a schematic plan view of an acoustic wave device according to the tenth example embodiment.

The present example embodiment is different from the first example embodiment in that the width of each electrode finger of the IDT electrode 61 is changed in the electrode finger extension direction. Except for the above points, the acoustic wave device according to the present example embodiment has the same or substantially the same configuration as the acoustic wave device 10 according to the first example embodiment.

The widths of all of the first electrode fingers 68 and all of the second electrode fingers 69 are changed so as to narrow from the proximal end portion side to the distal end portion side. The mass-added film 17 is provided one by one on all of the first electrode fingers 68 and all of the second electrode fingers 69. The width of the mass-added film 17 is changed in the mass-added film 17 from a portion provided on the proximal end portion side of the electrode finger to a portion provided on the distal end portion side of the electrode finger.

In the present example embodiment, both of the width of the electrode finger and the width of the mass-added film 17 are changed in the electrode finger extension direction. As a result, it is possible to further disperse the frequency at which the unwanted waves are excited, and it is possible to further reduce the strength of the unwanted waves as a whole. That is, it is possible to further reduce or prevent the unwanted waves.

It is sufficient that the width of at least one electrode finger is changed in the electrode finger extension direction. In this case, it is preferable that, among the electrode fingers provided with the mass-added film 17, the width of at least one electrode finger is changed in the electrode finger extension direction. As a result, it is possible to effectively disperse the frequency at which the unwanted waves are excited.

It is more preferable that the inclination of the change in the width of the electrode finger with respect to the electrode finger extension direction is different from the inclination of the change in the width of the mass-added film 17 provided on the electrode finger with respect to the electrode finger extension direction. As a result, it is possible to effectively disperse the frequency at which the unwanted waves are excited. However, both inclinations may be the same.

In the present example embodiment, the width of the electrode finger is changed so as to narrow from the proximal end portion side to the distal end portion side. The width of the electrode finger may be changed so as to widen from the proximal end portion side to the distal end portion side. Alternatively, the electrode finger may include both a portion in which the width is changed so as to narrow from the proximal end portion side toward the distal end portion side and a portion in which the width is changed so as to widen from the proximal end portion side toward the distal end portion side.

The mass-added film in the present example embodiment is configured in the same or substantially the same manner as in the first example embodiment. However, the configuration of the mass-added film may be a configuration of other example embodiments according to the present invention, such as the second to eighth example embodiments. Alternatively, similarly to the ninth example embodiment, the shapes of the plurality of mass-added films in plan view may be different from each other. Even in these cases, it is possible to reduce or prevent the unwanted waves.

The acoustic wave device according to the present invention can be used, for example, in a filter device. This example is described in the eleventh example embodiment.

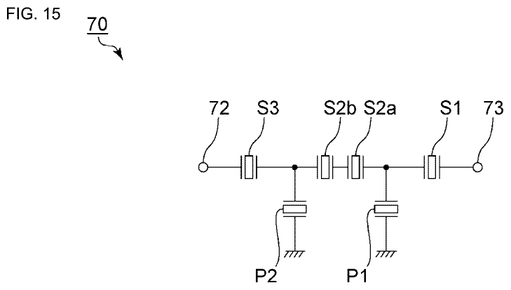

FIG. 15 is a circuit diagram of a filter device according to the eleventh example embodiment of the present invention.

A filter device 70 is, for example, a ladder filter. The filter device 70 includes a first signal terminal 72, a second signal terminal 73, a plurality of series arm resonators, and a plurality of parallel arm resonators. In the present example embodiment, all series arm resonators and all parallel arm resonators are acoustic wave resonators.

The first signal terminal 72 and the second signal terminal 73 may be configured as, for example, electrode pads, or may be configured as wirings. In the present example embodiment, the first signal terminal 72 is an antenna terminal. The antenna terminal is connected to an antenna.

Specifically, the plurality of series arm resonators of the filter device 70 include a series arm resonator S1, a series arm resonator S2a, a series arm resonator S2b, and a series arm resonator S3. Specifically, the plurality of parallel arm resonators include a parallel arm resonator P1 and a parallel arm resonator P2.

The series arm resonator S1, the series arm resonator S2a, the series arm resonator S2b, and the series arm resonator S3 are connected in series to each other between the first signal terminal 72 and the second signal terminal 73. The series arm resonator S2a and the series arm resonator S2b are split acoustic wave resonators. More specifically, the series arm resonator S2a and the series arm resonator S2b are acoustic wave resonators split in series.

The parallel arm resonator P1 is connected between a connection point between the series arm resonator S1 and the series arm resonator S2a and the ground potential. The parallel arm resonator P2 is connected between a connection point between the series arm resonator S2b and the series arm resonator S3 and the ground potential. The circuit configuration of the filter device 70 is not limited to the above-described configuration.

In the present example embodiment, one series arm resonator S2a of the split acoustic wave resonators is an acoustic wave device according to an example embodiment of the present invention. The other series arm resonator S2b of the split acoustic wave resonator does not include the mass-added film. In the series arm resonator S2a, it is possible to reduce or prevent unwanted waves. As a result, it is possible to reduce or prevent the deterioration of the filter characteristics in the filter device 70. In addition, the series arm resonator S2b included in the plurality of split acoustic wave resonators does not include a mass-added film. As a result, it is possible to reduce or prevent the deterioration of the loss in the filter device 70.

It is sufficient that the filter device 70 includes a plurality of the split acoustic wave resonators.

The plurality of split acoustic wave resonators may be a plurality of series arm resonators split in series or a plurality of series arm resonators split in parallel. Alternatively, the plurality of split acoustic wave resonators may be a plurality of parallel arm resonators split in series or a plurality of parallel arm resonators split in parallel.

The plurality of split acoustic wave resonators may be, for example, a plurality of acoustic wave resonators split into three or more. At least one of the plurality of split acoustic wave resonators may be an acoustic wave device according to an example embodiment of the present invention. At least one of the others of the plurality of split acoustic wave resonators need not include the mass-added film. As a result, it is possible to reduce or prevent the unwanted waves in the acoustic wave resonator, and it is possible to reduce or prevent the deterioration of the filter characteristics in the filter device 70 without causing the deterioration of the loss.

At least one acoustic wave resonator in the filter device 70 may be an acoustic wave device according to an example embodiment of the present invention. For example, at least one of the acoustic wave resonators other than the split acoustic wave resonator may be an acoustic wave device according to an example embodiment of the present invention. Even in this case, it is possible to reduce or prevent the unwanted waves in the acoustic wave resonator which is an acoustic wave device according to an example embodiment of the present invention. As a result, it is possible to reduce or prevent the deterioration of the filter characteristics in the filter device 70.

Hereinafter, the details of the thickness shear mode will be described. The “electrode” in the IDT electrode (to be described later) corresponds to an electrode finger. The support in the following example corresponds to a support substrate.

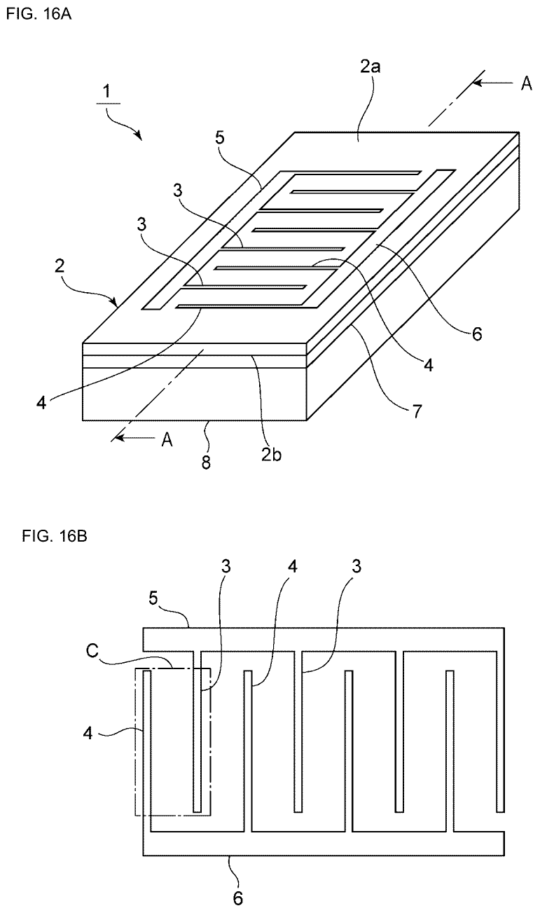

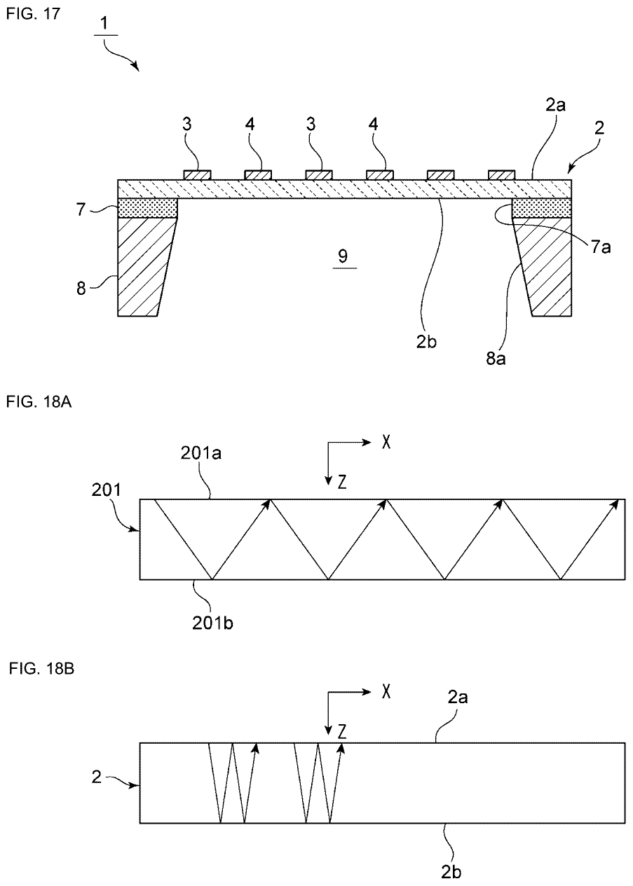

FIG. 16A is a schematic perspective view showing an appearance of the acoustic wave device using the bulk wave in the thickness shear mode, FIG. 16B is a plan view showing the electrode structure on the piezoelectric layer, and FIG. 17 is a sectional view of a portion taken along line A-A in FIG. 16A.

An acoustic wave device 1 includes a piezoelectric layer 2 made of LiNbO₃, for example. The piezoelectric layer 2 may be made of LiTaO₃, for example. Cut-angles of LiNbO₃ or LiTaO₃ are Z-cut, but may be a rotated Y-cut or X-cut. The thickness of the piezoelectric layer 2 is not particularly limited, but is, for example, preferably about 40 nm or larger and about 1000 nm or smaller, and more preferably about 50 nm or larger and about 1000 nm or smaller in order to effectively excite the thickness shear mode. The piezoelectric layer 2 includes first and second main surfaces 2a and 2b facing each other. The electrode 3 and the electrode 4 are provided on the first main surface 2a. Here, the electrode 3 is an example of a “first electrode”, and the electrode 4 is an example of a “second electrode”. In FIGS. 16A and 16B, the plurality of electrodes 3 are a plurality of first electrode fingers connected to a first busbar 5. The plurality of electrodes 4 are a plurality of second electrode fingers connected to a second busbar 6. The plurality of electrodes 3 and the plurality of electrodes 4 are interdigitated with each other. The electrode 3 and the electrode 4 have a rectangular or substantially rectangular shape, and have a length direction. The electrode 3 and the electrode 4 adjacent thereto face each other in a direction orthogonal or substantially orthogonal to the length direction. Both the length direction of the electrodes 3 and 4 and the direction orthogonal or substantially orthogonal to the length direction of the electrodes 3 and 4 are directions intersecting the thickness direction of the piezoelectric layer 2. Therefore, it can be said that the electrode 3 and the electrode 4 adjacent thereto face each other in the direction intersecting the thickness direction of the piezoelectric layer 2. In addition, the length direction of the electrodes 3 and 4 may be changed to the direction orthogonal or substantially orthogonal to the length direction of the electrodes 3 and 4 shown in FIGS. 16A and 16B. That is, in FIGS. 16A and 16B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 16A and 16B. A plurality of pairs of structures in which the electrode 3 connected to one potential and the electrode 4 connected to the other potential are adjacent to each other are provided in a direction orthogonal or substantially orthogonal to the length direction of the electrodes 3 and 4. Here, a case where the electrodes 3 and 4 are adjacent to each other does not mean a case where the electrodes 3 and 4 are disposed to be in direct contact with each other, but means a case where the electrodes 3 and 4 are disposed with a distance therebetween. In addition, in a case where the electrodes 3 and 4 are adjacent to each other, the electrode connected to a hot electrode or a ground electrode, including the other electrodes 3 and 4, is not disposed between the electrodes 3 and 4. The number of pairs does not need to be integer pairs, but may be 1.5 pairs, 2.5 pairs, or the like. A center-to-center distance, that is, a pitch between the electrodes 3 and 4 is, for example, preferably in a range of about 1 μm or larger and about 10 μm or smaller. In addition, the widths of the electrodes 3 and 4, that is, the dimensions of the electrodes 3 and 4 in the facing direction are, for example, preferably in a range of about 50 nm or larger and about 1,000 nm or smaller, and more preferably in a range of about 150 nm or larger and about 1,000 nm or smaller. The center-to-center distance between the electrodes 3 and 4 is a distance connecting the center of the dimension (width dimension) of the electrode 3 in the direction orthogonal to the length direction of the electrode 3 and the center of the dimension (width dimension) of the electrode 4 in the direction orthogonal or substantially orthogonal to the length direction of the electrode 4.

In addition, in the acoustic wave device 1, since the Z-cut piezoelectric layer is used, the direction orthogonal or substantially orthogonal to the length direction of the electrodes 3 and 4 is a direction orthogonal or substantially orthogonal to a polarization direction of the piezoelectric layer 2. In a case where piezoelectric materials with different cut-angles are used as the piezoelectric layer 2, this case is an exception. Here, the description of “orthogonal” is not limited to being strictly orthogonal, but may be substantially orthogonal (angle formed between the direction orthogonal to the length direction of the electrodes 3 and 4 and the polarization direction falls within a range of about 90°±10°, for example).

A support 8 is laminated on the second main surface 2b side of the piezoelectric layer 2 with an insulating layer 7 interposed therebetween. The insulating layer 7 and the support 8 have a frame shape and include through-holes 7a and 8a as shown in FIG. 17. In this manner, a cavity portion 9 is provided. The cavity portion 9 is provided not to disturb the vibration of the excitation region C of the piezoelectric layer 2. Therefore, the support 8 is laminated on the second main surface 2b with the insulating layer 7 interposed therebetween at a position not overlapping the portion where at least the pair of electrodes 3 and 4 are provided. The insulating layer 7 does not have to be provided. Therefore, the support 8 can be directly or indirectly laminated on the second main surface 2b of the piezoelectric layer 2.

The insulating layer 7 is made of silicon oxide, for example. However, in addition to silicon oxide, an appropriate insulating material such as, for example, silicon oxynitride or alumina can be used. The support 8 is made of Si, for example. A plane orientation of a surface of Si on the piezoelectric layer 2 side may be (100), (110), or (111). It is preferable that Si of the support 8 is high resistance having a resistivity of, for example, about 4 kΩcm or higher. However, the support 8 can also be made of an appropriate insulating material or semiconductor material.

Examples of the material of the support 8 include piezoelectric materials such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrodes 3 and 4 and the first and second busbars 5 and 6 are made of appropriate metals or alloys such as Al and AlCu alloys, for example. In the acoustic wave device 1, the electrodes 3 and 4 and the first and second busbars 5 and 6 have, for example, a structure in which Al films are laminated on a Ti film. A close contact layer other than the Ti film may be used.

During driving, the AC voltage is applied between the plurality of electrodes 3 and the plurality of electrodes 4. More specifically, the AC voltage is applied between the first busbar 5 and the second busbar 6. In this manner, it is possible to obtain the resonance characteristics using the bulk wave in the thickness shear mode excited in the piezoelectric layer 2. In addition, in the acoustic wave device 1, in a case where the thickness of the piezoelectric layer 2 is defined as d and the center-to-center distance between any electrodes 3 and 4 adjacent to each other in the plurality of pairs of electrodes 3 and 4 is defined as p, d/p is, for example, about 0.5 or smaller. In this manner, the bulk wave in the thickness shear mode is effectively excited, and satisfactory resonance characteristics can be obtained. More preferably, for example, d/p is about 0.24 or smaller, and in this case, more satisfactory resonance characteristics can be obtained.

In the acoustic wave device 1, since the above-described configuration is provided, even in a case where the number of pairs of the electrodes 3 and 4 is reduced in order to reduce the size, the Q value is unlikely to be decreased. The reason is that a propagation loss is small even when the number of electrode fingers in reflectors on both sides is reduced. In addition, the number of electrode fingers can be reduced by using the bulk wave in the thickness shear mode. A difference between the Lamb wave used in the acoustic wave device and the bulk wave in the thickness shear mode will be described with reference to FIGS. 18A and 18B.

FIG. 18A is a schematic elevational sectional view showing the Lamb wave that propagates through the piezoelectric film of the acoustic wave device as disclosed in Japanese Unexamined Patent Application Publication No. 2012-257019. Here, the wave propagates in a piezoelectric film 201 as indicated by arrows. Here, in the piezoelectric film 201, a first main surface 201a and a second main surface 201b face each other, and the thickness direction connecting the first main surface 201a and the second main surface 201b is a Z direction. An X direction is a direction in which the electrode fingers of the IDT electrodes are arranged. As shown in FIG. 18A, in the Lamb wave, the wave propagates in the X direction as shown in the figure. Since the wave is a plate wave, the piezoelectric film 201 vibrates as a whole. Since the wave propagates in the X direction, the reflectors are disposed on both sides to obtain the resonance characteristics. Therefore, the propagation loss of the wave occurs, and the Q value is decreased in a case where the size reduction is attempted, that is, in a case where the number of pairs of the electrode fingers is decreased.

On the other hand, as shown in FIG. 18B, in the acoustic wave device 1, since the vibration displacement is a thickness shear direction, the wave propagates and resonates in the direction connecting the first main surface 2a and the second main surface 2b of the piezoelectric layer 2, that is, the Z direction. That is, an X direction component of the wave is significantly smaller than a Z direction component. Since the resonance characteristics are obtained by the propagation of the wave in the Z direction, the propagation loss is less likely to occur even when the number of the electrode fingers of the reflector is reduced. Furthermore, even in a case where the number of pairs of the electrode pair consisting of the electrodes 3 and 4 is reduced when the size reduction is attempted, the Q value is unlikely to be decreased.

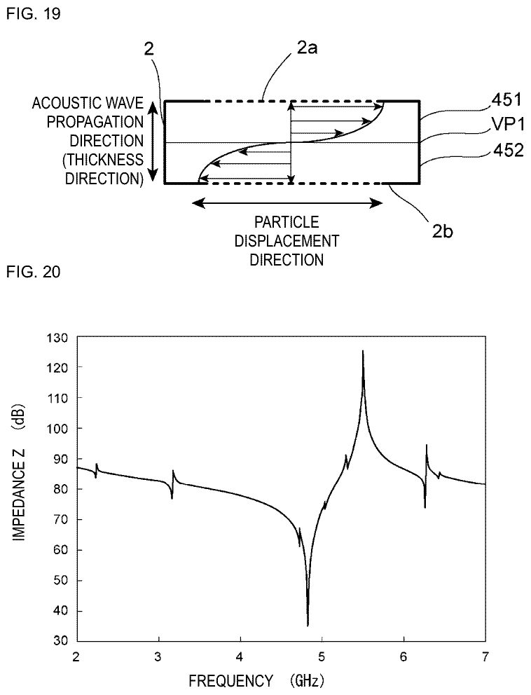

Amplitude directions of the bulk waves of the thickness shear mode are opposite to each other between a first region 451 included in the excitation region C of the piezoelectric layer 2 and a second region 452 included in the excitation region C, as shown in FIG. 19. FIG. 19 schematically shows the bulk waves in a case where the voltage is applied between the electrodes 3 and 4 so that the potential of the electrode 4 is higher than the potential of the electrode 3. The first region 451 is a region of the excitation region C between a virtual plane VP1, which is orthogonal or substantially orthogonal to the thickness direction of the piezoelectric layer 2 and bisects the piezoelectric layer 2, and the first main surface 2a. The second region 452 is a region of the excitation region C between the virtual plane VP1 and the second main surface 2b.

As described above, in the acoustic wave device 1, although at least one pair of electrodes including the electrodes 3 and 4 are disposed, the waves are not propagated in the X direction, and thus the number of pairs of the electrode pair including the electrodes 3 and 4 does not have to be plural. That is, at least one pair of electrodes need only be provided.

For example, the electrode 3 is an electrode connected to a hot potential and the electrode 4 is an electrode connected to a ground potential. However, the electrode 3 may be connected to the ground potential and the electrode 4 may be connected to the hot potential. In the acoustic wave device 1, at least one pair of electrodes are the electrodes connected to the hot potential or the electrodes connected to the ground potential, as described above, and no floating electrodes are provided.

FIG. 20 is a view showing the resonance characteristics of the acoustic wave device shown in FIG. 17. The design parameters of the acoustic wave device 1 with the resonance characteristics are as follows.

Piezoelectric layer 2: LiNbO₃ with Euler angles (0°, 0°, 90°), thickness=about 400 nm.

When viewed in the direction orthogonal to the length direction of the electrodes 3 and 4, the region in which the electrodes 3 and 4 overlap each other, that is, the length of the excitation region C=about 40 μm, the number of pairs of the electrodes including the electrodes 3 and 4=21 pairs, the center distance between the electrodes=about 3 μm, the width of the electrodes 3 and 4=about 500 nm, and d/p=about 0.133.

Insulating layer 7: silicon oxide film having the thickness of about 1 μm.

Support 8: Si.

The length of the excitation region C is the dimension in the length direction of the electrodes 3 and 4 of the excitation region C.

In the acoustic wave device 1, an electrode-to-electrode distance of the electrode pair consisting of the electrodes 3 and 4 is made equal or substantially equal in all the plurality of pairs. That is, the electrodes 3 and 4 are disposed at equal or substantially equal pitches.

As is clear from FIG. 20, good resonance characteristics with the fractional bandwidth of, for example, about 12.5% are obtained regardless of the presence of the reflector.

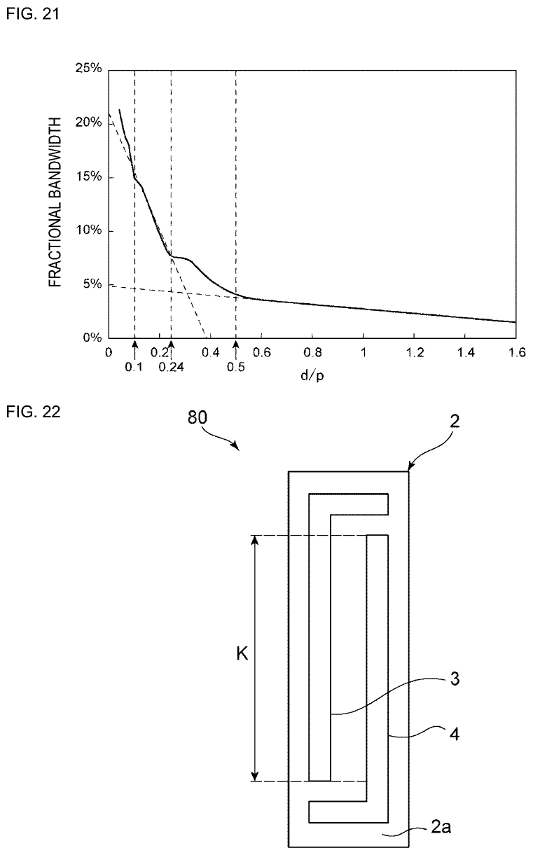

In a case where the thickness of the piezoelectric layer 2 is defined as d and the center-to-center distance between the electrodes 3 and 4 is defined as p, in the acoustic wave device 1, as described above, for example, d/p is about 0.5 or less, more preferably about 0.24 or less. The description thereof will be made with reference to FIG. 21.

A plurality of acoustic wave devices are obtained by changing d/p in the same manner as the acoustic wave device that obtains the resonance characteristics shown in FIG. 20. FIG. 21 is a view showing a relationship between d/p and the fractional bandwidth as the resonator of the acoustic wave device.

As is clear from FIG. 21, when d/p>about 0.5, the fractional bandwidth is less than about 5% even in a case where d/p is adjusted. On the other hand, in a case where d/p≤about 0.5, when d/p is changed within this range, the fractional bandwidth of about 5% or more can be obtained, that is, the resonator having a high coupling coefficient can be provided. In addition, in a case where d/p is about 0.24 or smaller, the fractional bandwidth can be increased to about 7% or larger. In addition, when d/p is adjusted within this range, a resonator having a wider fractional bandwidth can be obtained, and a resonator having a higher coupling coefficient can be obtained. Therefore, it can be seen that, by adjusting d/p to, for example, about 0.5 or less, it is possible to configure a resonator having a high coupling coefficient using the bulk wave in the thickness shear mode.

FIG. 22 is a plan view of the acoustic wave device using the bulk wave in the thickness shear mode. In an acoustic wave device 80, the pair of electrodes including the electrode 3 and electrode 4 are provided on the first main surface 2a of the piezoelectric layer 2. K in FIG. 22 is an intersecting width. As described above, in the acoustic wave device according to the present invention, the number of pairs of the electrodes may be one pair. Even in this case, when d/p is, for example, about 0.5 or less, it is possible to effectively excite the bulk wave in the thickness shear mode.

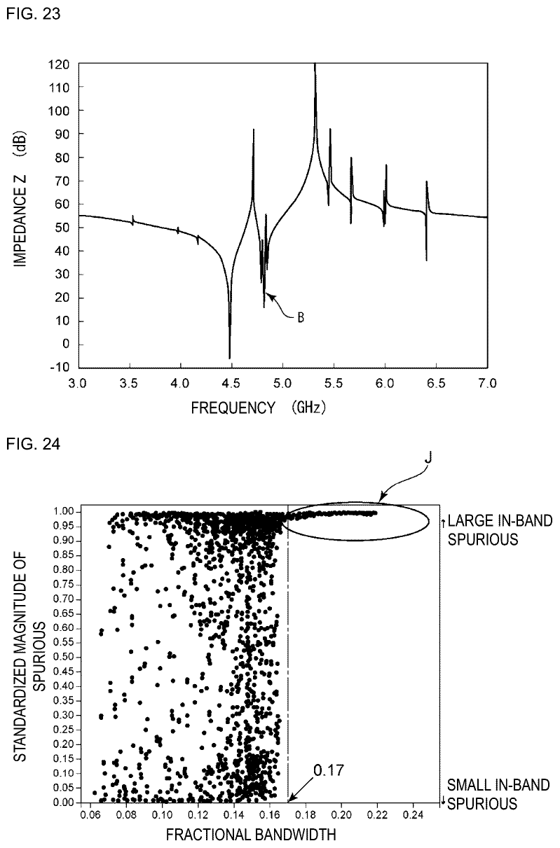

In the acoustic wave device 1, preferably, the metallization ratio MR of any electrodes 3 and 4 adjacent to each other among the plurality of electrodes 3 and 4 to the excitation region C, which is the region in which the electrodes 3 and 4 adjacent to each other overlap each other when viewed in the facing direction, satisfies MR≤about 1.75(d/p)+0.075, for example. In this case, the spurious can be effectively reduced. The description thereof will be made with reference to FIGS. 23 and 24. FIG. 23 is a reference view showing an example of the resonance characteristics of the acoustic wave device 1. The spurious indicated by an arrow B appears between the resonant frequency and the anti-resonant frequency. For example, d/p=about 0.08 and the Euler angles of LiNbO₃ are (0°, 0°, 90°). In addition, for example, the metallization ratio MR is about 0.35.

The metallization ratio MR will be described with reference to FIG. 16B. In the electrode structure of FIG. 16B, it is assumed that, when focusing on the pair of electrodes 3 and 4, only the pair of electrodes 3 and 4 are provided. In this case, a portion surrounded by a one-dot chain line is the excitation region C. The excitation region C is a region that overlaps the electrode 4 in the electrode 3 when the electrode 3 and the electrode 4 are viewed in the direction orthogonal to the length direction of the electrodes 3 and 4, that is, in the facing direction, a region that overlaps the electrode 3 in the electrode 4, and a region in which the electrode 3 and the electrode 4 overlap each other in the region between the electrode 3 and the electrode 4. An area of the electrodes 3 and 4 inside the excitation region C with respect to an area of the excitation region C is the metallization ratio MR. That is, the metallization ratio MR is a ratio of an area of the metallization portion to the area of the excitation region C.

In a case where the plurality of pairs of electrodes are provided, a ratio of the metallization portion included in the entire excitation region to a total area of the excitation region need only be MR.

FIG. 24 is a view showing a relationship between a fractional bandwidth and a phase rotation amount of an impedance of the spurious standardized at about 180 degrees as a magnitude of the spurious in a case where a large number of acoustic wave resonators are configured according to the form of the acoustic wave device 1. The fractional bandwidth is adjusted by changing the film thickness of the piezoelectric layer and the dimensions of the electrodes. In addition, FIG. 24 shows the results in a case where the piezoelectric layer made of the Z-cut LiNbO₃ is used, but the same tendency is obtained in a case where piezoelectric layers with other cut-angles are used.

In a region surrounded by an ellipse J in FIG. 24, the spurious is as large as about 1.0. As is clear from FIG. 24, in a case where the fractional bandwidth exceeds 0.17, that is, exceeds about 17%, a large spurious with a spurious level of about 1 or more appears in a pass band even when the parameters constituting the fractional bandwidth are changed. That is, as in the resonance characteristics shown in FIG. 23, a large spurious indicated by an arrow B appears within the band. Therefore, the fractional bandwidth is, for example, preferably about 17% or smaller. In this case, by adjusting the film thickness of the piezoelectric layer 2 and the dimensions of the electrodes 3 and 4, the spurious mode can be reduced.

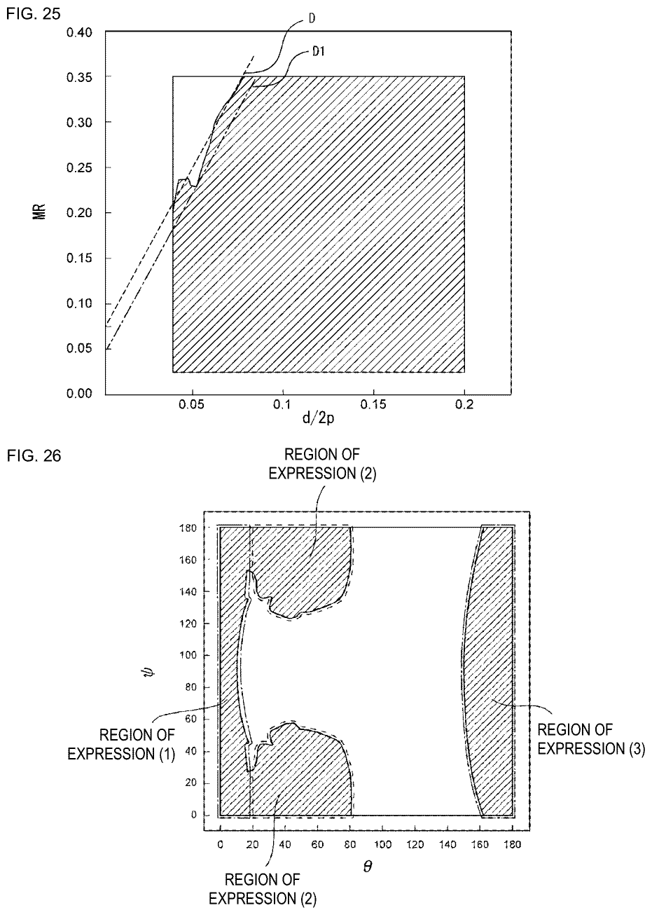

FIG. 25 is a view showing a relationship between d/2p, the metallization ratio MR, and the fractional bandwidth. In the acoustic wave device described above, various acoustic wave devices having different d/2p and MR are configured, and the fractional bandwidth is measured. A hatched portion on a right side of a broken line D in FIG. 25 is a region in which the fractional bandwidth is about 17% or less. A boundary between the hatched region and the non-hatched region is expressed by MR=about 3.5(d/2p)+0.075. That is, MR=about 1.75(d/p)+0.075. Therefore, preferably, MR about 1.75(d/p)+0.075, for example. In this case, it is easy to set the fractional bandwidth to about 17% or less. More preferably, it is a region on a right side of MR=about 3.5(d/2p)+0.05 indicated by a one-dot chain line D1 in FIG. 25. That is, for example, when MR about 1.75(d/p)+0.05, the fractional bandwidth can be reliably set to about 17% or less.

FIG. 26 is a view showing a map of the fractional bandwidth with respect to Euler angles (0°, θ, ψ) of LiNbO₃ in a case where d/p is infinitely close to 0. A hatched portion in FIG. 26 is a region in which the fractional bandwidth of at least about 5% or more is obtained, and in a case where a range of the region is approximated, the range is a range represented by Expression (1), Expression (2), and Expression (3).

$$( 0 ° \pm 10 ° , 0 ° to 20 ° , any ψ ) \qquad Expression ( 1 )$$

$$( 0 ° \pm 10 ° , 20 ° to 80 ° , 0 ° to 60 {° ( 1 - {( θ - 50 )}^{2} / 900 )}^{1 / 2} ) or \qquad Expression ( 2 )$$

$$( 0 ° \pm 10 ° , 20 ° to 80 ° , [ 180 ° - 60 {° ( 1 - {( θ - 50 )}^{2} / 900 )}^{1 / 2} ] to 180 ° )$$

$$( 0 ° \pm 10 ° , [ 180 ° - 30 {° ( 1 - {( ψ - 90 )}^{2} / 8100 )}^{1 / 2} ] to \\ 180 ° , and ψ ) \qquad Expression ( 3 )$$

Therefore, in a case of the Euler angles range of Expression (1), Expression (2), or Expression (3), it is preferable since the fractional bandwidth can be sufficiently widened. The same applies to a case where the piezoelectric layer 2 is the lithium tantalate layer.

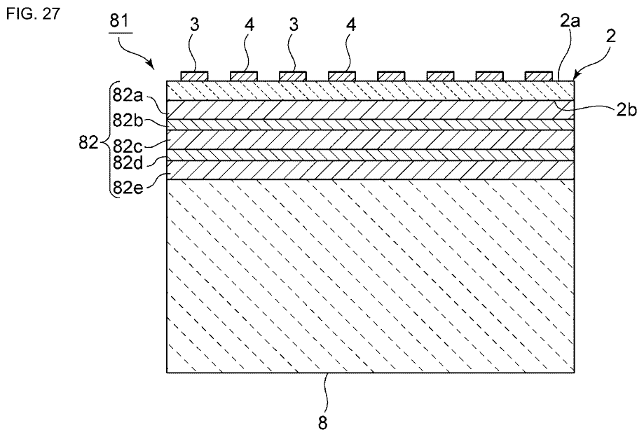

FIG. 27 is an elevational sectional view of the acoustic wave device including the acoustic multilayer film.

In an acoustic wave device 81, an acoustic multilayer film 82 is laminated on the second main surface 2b of the piezoelectric layer 2. The acoustic multilayer film 82 has a lamination structure of low acoustic impedance layers 82a, 82c, and 82e having a relatively low acoustic impedance and high acoustic impedance layers 82b and 82d having a relatively high acoustic impedance. In a case where the acoustic multilayer film 82 is used, the bulk wave in the thickness shear mode can be confined in the piezoelectric layer 2 without using the cavity portion 9 in the acoustic wave device 1. In the acoustic wave device 81 as well, the resonance characteristics based on the bulk wave in the thickness shear mode can be obtained by setting d/p to about 0.5 or smaller, for example. In the acoustic multilayer film 82, the number of laminated layers of the low acoustic impedance layers 82a, 82c, and 82e and the high acoustic impedance layers 82b and 82d is not particularly limited. At least one layer of the high acoustic impedance layers 82b and 82d may be disposed on a side farther from the piezoelectric layer 2 than the low acoustic impedance layers 82a, 82c, and 82e.

The low acoustic impedance layers 82a, 82c, and 82e and the high acoustic impedance layers 82b and 82d can be made of appropriate material as long as the above-described relationship of the acoustic impedance is satisfied. Examples of the materials of the low acoustic impedance layers 82a, 82c, and 82e include silicon oxide, silicon oxynitride, and the like. In addition, examples of the materials of the high acoustic impedance layers 82b and 82d include alumina, silicon nitride, and metal.

In the acoustic wave devices according to the first to tenth example embodiments, for example, the acoustic multilayer film 82 shown in FIG. 27 may be provided as the acoustic reflection film between the support and the piezoelectric layer. Specifically, the support and the piezoelectric layer may be disposed such that at least a portion of the support and at least a portion of the piezoelectric layer face each other with the acoustic multilayer film 82 interposed therebetween. In this case, in the acoustic multilayer film 82, it is sufficient that the low acoustic impedance layer and the high acoustic impedance layer are alternately laminated. The acoustic multilayer film 82 may be the acoustic reflection portion in the acoustic wave device.

In the acoustic wave devices according to the first to tenth example embodiments that use the bulk wave in the thickness shear mode, as described above, d/p is, for example, preferably about 0.5 or less, and more preferably about 0.24 or less. As a result, better resonance characteristics can be obtained. Furthermore, in the excitation regions in the acoustic wave devices according to the first to tenth example embodiments that use the bulk wave in the thickness shear mode, as described above, preferably, MR about 1.75 (d/p)+0.075 is satisfied, for example. In this case, it is possible to more reliably reduce or prevent the spurious mode.

It is preferable that the piezoelectric layers in the acoustic wave devices according to the first to tenth example embodiments, that use the bulk wave in the thickness shear mode are the lithium niobate layer or the lithium tantalate layer, for example. It is preferable that the Euler angles (φ, θ, ψ) of lithium niobate or lithium tantalate forming the piezoelectric layer fall within the range of Expression (1), Expression (2), or Expression (3). In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate;
a piezoelectric layer on the support;
an IDT electrode on the piezoelectric layer and including a pair of busbars facing each other and a plurality of electrode fingers; and
a plurality of mass-added films on the plurality of electrode fingers; wherein
an acoustic reflection portion is provided on or in the support at a position overlapping at least a portion of the IDT electrode in plan view in a lamination direction of the support and the piezoelectric layer;
d/p is about 0.5 or less, where d is a thickness of the piezoelectric layer and p is a center-to-center distance between adjacent electrode fingers of the plurality of electrode fingers;
each of the plurality of electrode fingers includes a proximal end portion connected to a corresponding one of the pair of busbars and a distal end portion facing the proximal end portion;
when viewed in an electrode finger orthogonal direction orthogonal or substantially orthogonal to an electrode finger extension direction in which the plurality of electrode fingers extend, a region in which the electrode fingers adjacent to each other overlap each other is an intersecting region, the intersecting region includes a central region, and a first edge region and a second edge region sandwiching the central region in the electrode finger extension direction and facing each other, and at least a portion of each of the plurality of mass-added films overlaps the central region in plan view;
each of the plurality of mass-added films on the plurality of electrode fingers is one of a mass-added film continuously provided from a proximal end portion side to a distal end portion side and a mass-added film intermittently provided from the proximal end portion side to the distal end portion side; and
when a dimension of each of the plurality of mass-added films in the electrode finger orthogonal direction is defined as a width of the respective mass-added film, the width is changed from a portion provided on the proximal end portion side to a portion provided on the distal end portion side in at least a portion of the respective mass-added film.

2. The acoustic wave device according to claim 1, wherein the width is continuously changed from the portion provided on the proximal end portion side to the portion provided on the distal end portion side in at least a portion of at least one of the plurality of mass-added films.

3. The acoustic wave device according to claim 1, wherein the width is changed stepwise from the portion provided on the proximal end portion side to the portion provided on the distal end portion side in at least a portion of at least one of the plurality of mass-added films.

4. The acoustic wave device according to claim 3, wherein
the mass-added film on at least one of the plurality of electrode fingers is the mass-added film intermittently provided from the proximal end portion side to the distal end portion side;
the mass-added film includes a plurality of film portions arranged in the electrode finger extension direction;
the width of each of the plurality of film portions does not change; and
the widths of adjacent film portions of the plurality of film portions are different from each other.

5. The acoustic wave device according to claim 3, wherein
the mass-added film on at least one of the electrode fingers is the mass-added film intermittently provided from the proximal end portion side to the distal end portion side;
the mass-added film includes a plurality of film portions arranged in the electrode finger extension direction; and
the width is changed from a portion provided on the proximal end portion side to a portion provided on the distal end portion side in at least a portion of the film portion.

6. The acoustic wave device according to claim 2, wherein the mass-added film on at least one of the electrode fingers is the mass-added film continuously provided from the proximal end portion side to the distal end portion side.

7. The acoustic wave device according to claim 1, wherein, in each of the plurality of mass-added films, the width of one of the portion provided on the proximal end portion side and the portion provided on the distal end portion side is equal to or wider than the width of another of the portion provided on the proximal end portion side and the portion provided on the distal end portion side.

8. The acoustic wave device according to claim 1, wherein each of the plurality of mass-added films includes a portion in which the width is changed so as to widen from the portion provided on the proximal end portion side to the portion provided on the distal end portion side, and a portion in which the width is changed so as to narrow from the portion provided on the proximal end portion side to the portion provided on the distal end portion side.

9. The acoustic wave device according to claim 1, wherein
regions positioned between the intersecting region and the pair of busbars include a pair of gap regions; and
each of the plurality of mass-added films overlaps the intersecting region and at least one of the pair of gap regions in plan view.

10. The acoustic wave device according to claim 1, wherein the plurality of mass-added films include a dielectric.

11. The acoustic wave device according to claim 10, wherein the plurality of mass-added films include silicon oxide.

12. The acoustic wave device according to claim 10, wherein a density of the plurality of mass-added films is higher than a density of the silicon oxide.

13. The acoustic wave device according to claim 1, wherein the plurality of mass-added films include a metal.

14. The acoustic wave device according to claim 1, wherein, when a dimension of the plurality of electrode fingers in the electrode finger orthogonal direction is defined as a width of the plurality of electrode fingers, the width of at least one of the plurality of electrode fingers is changed from the proximal end portion side to the distal end portion side.

15. The acoustic wave device according to claim 14, wherein
the width of at least one of the plurality of electrode fingers including the mass-added film is changed from the proximal end portion side to the distal end portion side; and
an inclination of a change in the width of the at least one electrode finger with respect to the electrode finger extension direction is different from an inclination of a change in the width of the mass-added film provided on the electrode finger with respect to the electrode finger extension direction.

16. The acoustic wave device according to claim 1, wherein d/p is about 0.24 or less.

17. The acoustic wave device according to claim 1, wherein an excitation region is a region in which adjacent electrode fingers of the plurality of electrode fingers overlap each other when viewed in the electrode finger orthogonal direction and is a region between centers of the adjacent electrode fingers in the electrode finger orthogonal direction; and
when a metallization ratio of the electrode fingers to the excitation region is defined as MR, MR about 1.75(d/p)+0.075 is satisfied.

18. The acoustic wave device according to claim 1, wherein the piezoelectric layer includes lithium tantalate or lithium niobate.

19. The acoustic wave device according to claim 18, wherein Euler angles (φ, θ, ψ) of lithium niobate or lithium tantalate of the piezoelectric layer fall within a range of Expression (1), Expression (2), or Expression (3):
$$( 0 ° \pm 10 ° , 0 ° to 20 ° , any ψ ) ; \qquad Expression ( 1 )$$
$$( 0 ° \pm 10 ° , 20 ° to 80 ° , 0 ° to 60 {° ( 1 - {( θ - 50 )}^{2} / 900 )}^{1 / 2} ) or \qquad Expression ( 2 )$$
$$( 0 ° \pm 10 ° , 20 ° to 80 ° , [ 180 ° - 60 {° ( 1 - {( θ - 50 )}^{2} / 900 )}^{1 / 2} ] to 180 ° ) ; and$$
$$( 0 ° \pm 10 ° , [ 180 ° - 30 {° ( 1 - {( ψ - 90 )}^{2} / 8100 )}^{1 / 2} ] to \\ 180 ° , and ψ ) . \qquad Expression ( 3 )$$

20. The acoustic wave device according to claim 1, wherein
the acoustic reflection portion includes a cavity portion; and
the support and the piezoelectric layer are positioned such that a portion of the support and a portion of the piezoelectric layer face each other with the cavity portion interposed between the support and the piezoelectric layer.

21. The acoustic wave device according to claim 1, wherein
the acoustic reflection portion includes an acoustic reflection film including a high acoustic impedance layer having a relatively high acoustic impedance and a low acoustic impedance layer having a relatively low acoustic impedance; and
the support and the piezoelectric layer are positioned such that at least a portion of the support and at least a portion of the piezoelectric layer face each other with the acoustic reflection film interposed between the support and the piezoelectric layer.

22. A filter device comprising:
a plurality of acoustic wave resonators including split acoustic wave resonators; wherein
at least one of the split acoustic wave resonators is defined by the acoustic wave resonator of the acoustic wave device according to claim 1; and
at least another one of the split acoustic wave resonators is an acoustic wave resonator that does not include the mass-added film of the acoustic wave device.
